(19) United States
(12) Patent Application Publication
(10) Pub. No.: US 2006/0063337 A1
(43) Pub. Date: Mar. 23, 2006

(54) Semiconductor device and manufacturing method thereof

(75) Inventor: Jea-Hee Kim, Yeoju-kun (KR)

Correspondence Address: THE LAW OFFICES OF ANDREW D. FORTNEY, PH.D., P.C., 7257 N. MAPLE AVENUE, BLDG. D, SUITE 107, FRESNO, CA, 93720, US

(73) Assignee: DongbuAnam Semiconductor Inc.

(21) Appl. No.: 11/228,992

(22) Filed: Sep. 16, 2005

(30) Foreign Application Priority Data
Sep. 17, 2004 (KR) 10-2004-0074497

(51) Int. Cl. H01L 21/336

(52) U.S. Cl. 438/287

(57) ABSTRACT

A method of manufacturing a semiconductor device includes forming a gate oxide layer on a substrate and forming a nitride layer on the surface of the oxide layer using nitrogen at a concentration of 9 to 11% as a plasma gas. With such scheme, the plasma nitridation method is used so that charge mobility can be preserved for an NMOS transistor and the boron penetration is prevented for a PMOS transistor in a semiconductor having a gate length of 100 nm or less.

### CROSS-REFERENCE TO RELATED APPLICATION

This application claims priority to and the benefit of Korean Patent Application No. 10-2004-0074497 filed in the Korean Intellectual Property Office on Sep. 17, 2004, the entire contents of which are incorporated herein by reference.

### BACKGROUND OF THE INVENTION

(a) Field of the Invention

The present invention relates to a semiconductor device and a manufacturing method thereof.

(b) Description of the Related Art

Generally, a gate-insulating layer has involved a silicon oxide layer in a MOSFET. As semiconductor devices are becoming more highly integrated and an operation speed thereof is increasing, a gate-insulating layer therein is becoming thinner and thinner. Accordingly, because of the thinness of the gate-insulating layer, boron penetration may sometimes occur between a gate electrode and a silicon substrate. Accordingly, for a semiconductor device having a very fine line structure (e.g., less than 0.18 μm), boron penetration from the gate electrode to the silicon substrate has generally been prevented by implanting nitrogen in the silicon oxide layer so as to form an oxynitride layer.

In more detail, when the boron moves from P+ polysilicon to a channel, the semiconductor device may suffer from a variance in its threshold voltage (Vth), an increase in the number of charge trap sites, a decrease in charge mobility, and a decrease of current due to a poly depletion.

The oxynitride layer used for such boron penetration provides features of boron-blocking, suppression of hot carrier degradation, and suppression of gate leakage, in comparison with a gate insulator consisting of a pure oxide layer (i.e., without added dopants or other components).

However, although the oxynitride layer has many merits for a PMOS transistor, it has a drawback for an NMOS transistor in that a saturation current (Idsat) may be decreased due to a decrease of charge mobility. Such a drawback may be caused because nitrogen can be deposited at the interface between the silicon substrate and the oxide layer, thereby decreasing the charge mobility.

Accordingly, in order to prevent the drawback in an NMOS transistor, new methods for forming a nitride layer have been developed, considering the profile of nitrogen. For example, for a semiconductor device of a 130 nm line scale, the nitride layer may be formed by thermal nitridation, even if the nitrogen profile is concentrated at the interface between the silicon (Si) substrate and the oxide (SiO₂) layer. However, for a semiconductor device of less than a 90 nm line scale, the nitride layer cannot be formed by such thermal nitridation, since such a thermal nitride layer does not provide desired transistor performance.

The above information disclosed in this Background section is only for enhancement of understanding of the background of the invention, and therefore, it may contain information that does not form information or prior art that is already known in this or any other country to a person of ordinary skill in the art.

### SUMMARY OF THE INVENTION

The present invention has been made in an effort to provide a semiconductor device and a manufacturing method thereof having advantages of preventing boron penetration in a PMOS device and minimizing a decrease of charge mobility in an NMOS device.

An exemplary method of manufacturing a semiconductor device according to an embodiment of the present invention includes forming a gate oxide layer on a substrate, and forming a nitride layer on a surface of the oxide layer using a plasma gas comprising nitrogen.

In forming the nitride layer, the nitrogen may have a concentration of 9% to 11%, and preferably of about 10%. Also, a plasma processing chamber may have a pressure of 6 to 8 Pa and preferably of about 7 Pa.

An exemplary semiconductor device according to an embodiment of the present invention includes a silicon substrate, a gate oxide layer on the silicon substrate, and a nitride layer concentrated on a surface of the gate oxide layer using a plasma gas comprising a predetermined concentration of nitrogen.

### BRIEF DESCRIPTION OF THE DRAWINGS

FIG. 1A illustrates a method for thermally forming a nitride layer. FIG. 1B illustrates a method for forming a nitride layer using plasma.

FIG. 2A to FIG. 2C are graphs illustrating a relationship between a binding energy and a binding strength between components of a nitride layer according to the nitrogen concentration, as measured by XPS.

FIG. 3 is a graph of nitrogen depth profiles for a thermal nitride layer and a plasma nitride layer, as measured by SIMS.

FIG. 4 is a graph illustrating an equivalent oxide thickness (EOT) difference for a thermal nitride layer and a plasma nitride layer.

FIG. 5 is a graph showing a comparison of EOT and a thickness of an oxide layer of an NMOS transistor obtained by a C-V method.

FIG. 6A is a graph showing a charge difference according to post processing of a plasma nitride layer. FIG. 6B is a graph showing an entire charge difference of an interface for a thermal nitride layer and a plasma nitride layer.

FIG. 7A to FIG. 7C are graphs of leakage currents in an NMOS transistor with respect to base oxide layers.

FIG. 8A and FIG. 8B are graphs of threshold voltages (Vth) with respect to lengths when a base oxide layer has a thickness of 20 Å.

FIG. 9A and FIG. 9B are graphs of threshold voltages (Vth) with respect to lengths when a base oxide layer has a thickness of 16 Å.

FIG. 10A and FIG. 10B are graphs of on-current (Ion) and off-current (Ioff) characteristics of an NMOS FET and a PMOS FET when a base oxide layer has a thickness of 20 Å.

FIG. 11A and FIG. 11B are graphs of on-current (Ion) and off-current (Ioff) characteristics of an NMOS FET and a PMOS FET when a base oxide layer has a thickness of 16 Å.

FIG. 12a to FIG. 13B are graphs of on-current (Ion) and off-current (Ioff) characteristics according to the oxidation and nitridation methods.

### DETAILED DESCRIPTION OF THE EMBODIMENTS

An exemplary embodiment of the present invention will hereinafter be described in detail with reference to the accompanying drawings.

With reference to the accompanying drawings, the present invention will be described in order for those skilled in the art to be able to implement the invention. As those skilled in the art would realize, the described embodiments may be modified in various different ways, all without departing from the spirit or scope of the present invention.

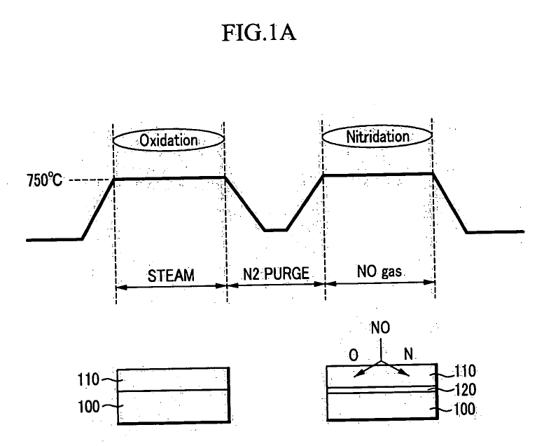

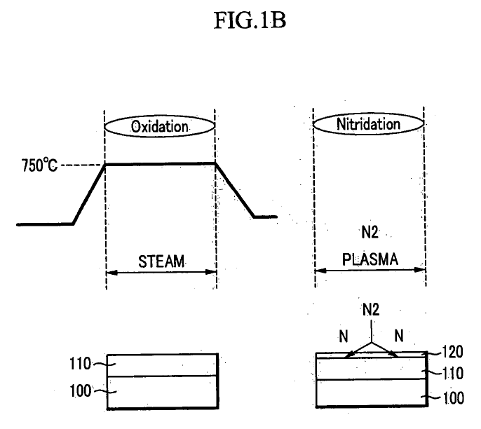

FIG. 1A illustrates a method for thermally a nitride layer, and FIG. 1B illustrates a method for forming a nitride layer using plasma. Nitridation methods may be classified into thermal nitridation methods and plasma nitridation methods.

In addition, gate oxide formation methods may be classified into torch methods and water vapor generator (WVG) methods, depending on how water or steam (H₂O) is generated. The WVG method may form a thinner oxide layer. The water or steam is typically generated by flame reaction in the torch method, while the water or steam is typically generated by a catalytic reaction in the WVG method.

At the same temperature, the amount of generated water vapor or steam can be controlled by the WVG method, while it generally cannot be controlled in the torch methods. That is, the reactants determine the amount of the generated steam in the WVG method, while the temperature determines the amount in the torch method.

According to one embodiment of the thermal nitridation method, as shown in FIG. 1A, a base oxide layer 110 may be formed first on a substrate 100 by a WVG method. The substrate 100 may comprise a p-type HAI wafer. Then, the nitride layer (Si₃N₄) 120 is formed at a temperature of 750° C. and under an atmosphere of less than 2% NO gas. In this case, the thermal nitride layer 120 is generally formed between the substrate 100 and the base oxide layer 110.

According to one embodiment of a plasma nitridation method, as shown in FIG. 1B, a base oxide layer 110 may be formed on the substrate 100 by a WVG method. Then, a nitride layer (Si₃N₄) 120 (which may be called a plasma nitride layer) is formed in and/or on the base oxide layer 110 using a plasma gas comprising nitrogen (preferably a nitrogen source that is substantially free of elements that may adversely affect the dielectric properties of the gate insulator film, such as carbon, hydrogen, metals, etc., such as N₂, N₂O, NO, etc.) Generally, the nitrogen source material is present at a concentration of from about 3% to about 25% (preferably from about 5% to about 15%) by volume, in an inert carrier gas, such as He, Ne, Ar, Kr, etc. Generally, the lower the nitrogen-to-oxygen ratio in the nitrogen source gas(es), the higher the concentration of nitrogen source material. In a preferred embodiment, the reactive species are generated in an N₂ plasma.

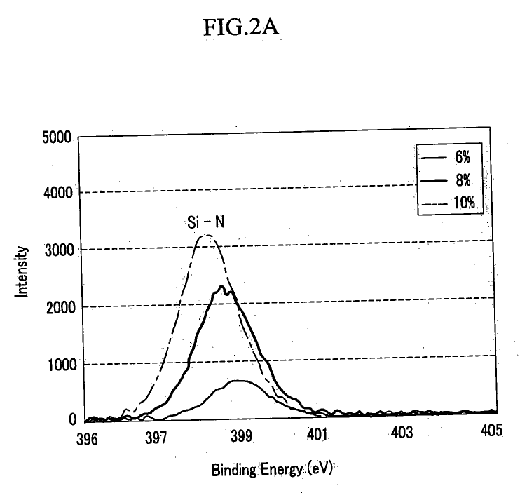

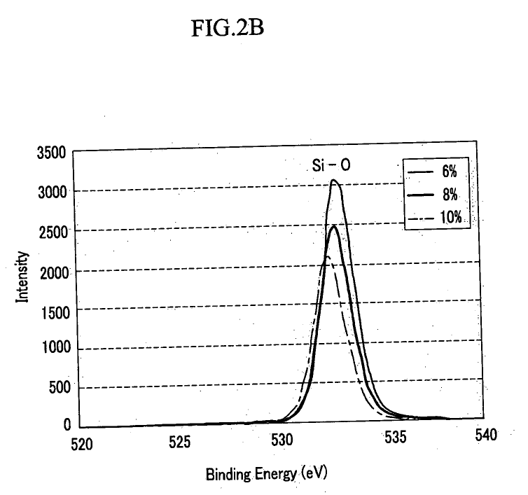

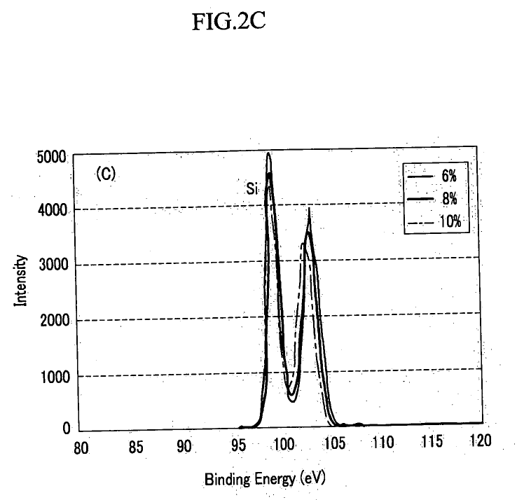

FIG. 2A to FIG. 2C are graphs illustrating a relationship between a binding energy and the binding strength between components of a nitride layer according to the nitrogen concentration measured by XPS. In this case, the gate oxide layer has a 16 Å thickness, and the nitrogen concentrations in the gases introduced into the plasma chamber are respectively 6%, 8%, and 10%.

Particularly, FIG. 2A illustrates a binding strength of Si—N and FIG. 2B illustrates a binding strength of Si—O.

As shown in FIG. 2A and FIG. 2B, the Si—N bond becomes greatest when the nitrogen concentration is 10%, and the Si—O bond becomes greatest when the nitrogen concentration is 6%. From such a result, it may be understood that the nitrogen is generally substituted for the oxygen (O atoms), rather than the silicon (Si atoms) in SiO₂ to form the nitride layer (Si₃N₄) 120.

However, as shown in FIG. 2C, the silicon peak is relatively constant, but in one case somewhat varied, for various nitrogen concentrations. Accordingly, it will be understood that the nitrogen may also partly substitute for the silicon.

The oxygen replaced by the nitrogen may be exhausted or it may combine with underlying silicon for a re-oxidization thereof. In this case, the rate of re-oxidation is most affected by pressure, and the re-oxidation thickness may increase as the residence time of the oxygen increases. Thus, the re-oxidation may cause the oxide layer 110 to become thicker. Accordingly, in order to reduce, minimize or prevent significant thickening of the oxide layer 110, the plasma nitridation may be performed at a chamber pressure of from 6 Pa to 8 Pa, preferably at about 7 Pa.

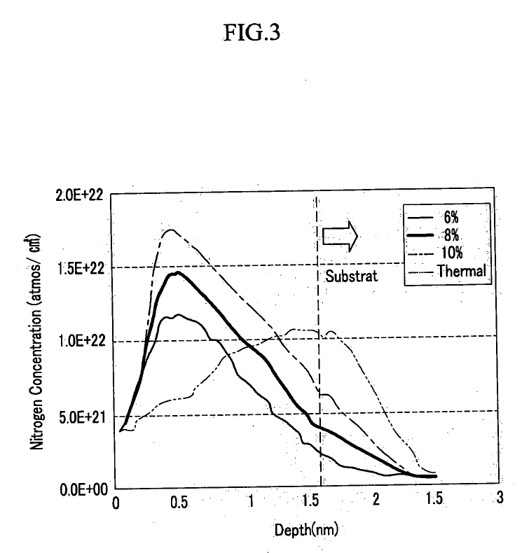

FIG. 3 is a graph of nitrogen depth profiles for a thermal nitride layer and a plurality of plasma nitride layers, as measured by secondary ion mass spectroscopy (SIMS). As shown in FIG. 3, the nitrogen tends to concentrate at or near the interface between the silicon substrate and the oxide layer in thermal nitridation, while it tends to concentrate on, at or near the exposed or upper surface of the oxide layer in plasma nitridation.

Accordingly, it may be understood that thermal nitridation may be a cause of the decrease of the charge mobility in an NMOS device. Also, it will be understood that, in plasma nitridation, the nitrogen profile is reduced or minimized at the interface between the silicon substrate and oxide layer so that the charge mobility does not significantly deteriorate in an NMOS device, while boron penetration is still generally suppressed in a PMOS device.

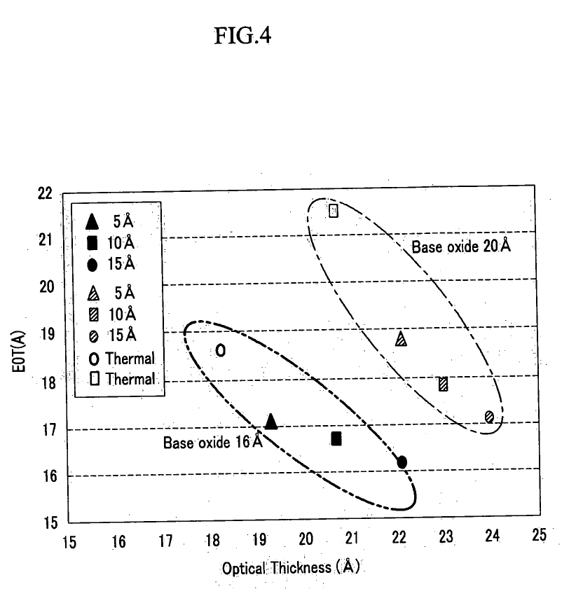

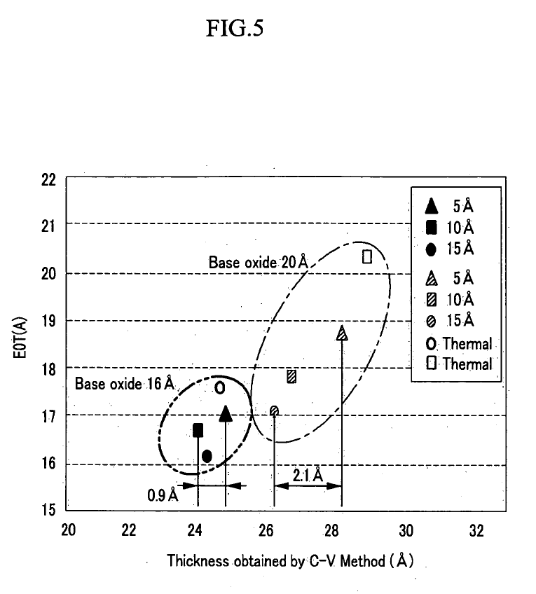

FIG. 4 is a graph illustrating an equivalent oxide thickness (EOT) difference for a variety of thermal nitride layers and plasma nitride layers.

As shown in FIG. 4, when the nitride layer is formed by thermal nitridation with a large EOT (equivalent oxide thickness) for both 16 Å and 20 Å base oxide layers 110, the EOT of the thermal nitride layer is generally larger than that of a corresponding plasma nitride layer. This may be because thermal nitridation uses a lesser density of nitrogen than plasma nitridation.

Plasma nitridation generally forms plasma nitride layers with different EOTs according to the nitrogen concentration. That is, the EOT becomes smaller as the nitrogen concentration increases, and the optical thickness becomes larger as the nitrogen concentration increases. This may be because nitrogen has a larger absorption coefficient k than that of the corresponding oxide, and the optical thickness is measured based on the absorption coefficient k of the oxide layer.

FIG. 5 is a graph showing a comparison of EOT and thickness of oxide layers for an NMOS transistor, as obtained by a C-V method. As shown in FIG. 5, when the base oxide layer 110 is thicker, the optical thickness may vary to a greater degree according to the nitrogen concentration. In addition, when the base oxide layer 110 is thinner, the difference of the EOT between the thermal nitride layer and the plasma nitride layer decreases. This may be because the thinner the base oxide layer is, the larger the leakage current of the bulk oxide layer, so precise measurement of the capacitance may be difficult.

Various models for measuring the optical thickness by the C-V method for the base oxide layer thinner than 16 Å will hereinafter be described in detail.

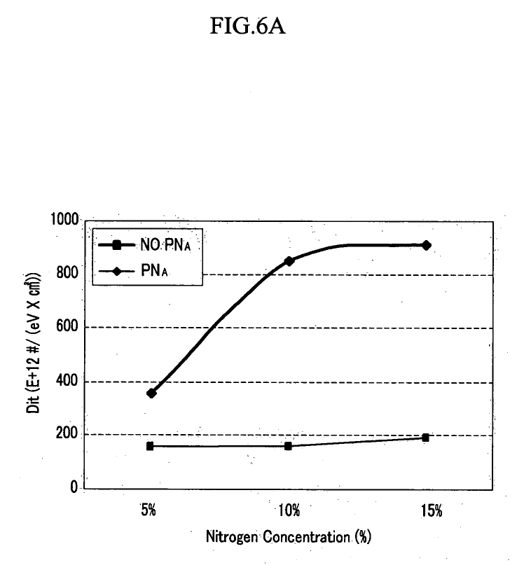

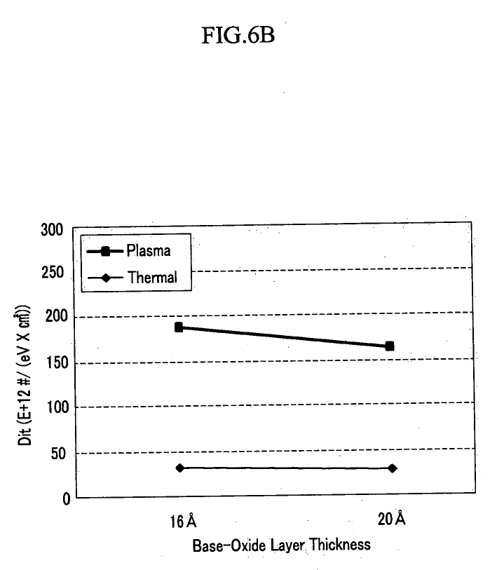

FIG. 6A is a graph showing a charge difference resulting from certain post processing of a plasma nitride layer, and FIG. 6B is a graph showing an entire charge difference of an interface for a thermal nitride layer and a plasma nitride layer.

As shown in FIG. 6B, a charge is less detected in the thermal nitride layer than in the plasma nitride layer. This may be because, in thermal nitridation, an amount of nitrogen that is not combined with other components at the interface is smaller in comparison with plasma nitridation.

In addition, as shown in FIG. 6A, when the plasma nitride layer is post-processed, the charge may be considerably more reduced than when the plasma nitride layer is not post-processed. This may be because, in plasma nitridation, implanted nitrogen that remains uncombined may be combined or out-diffused by certain post processing (e.g., under post-processing conditions of inert or N₂ gas flow, a temperature of about 1000° C., for a length of time of about 5 sec).

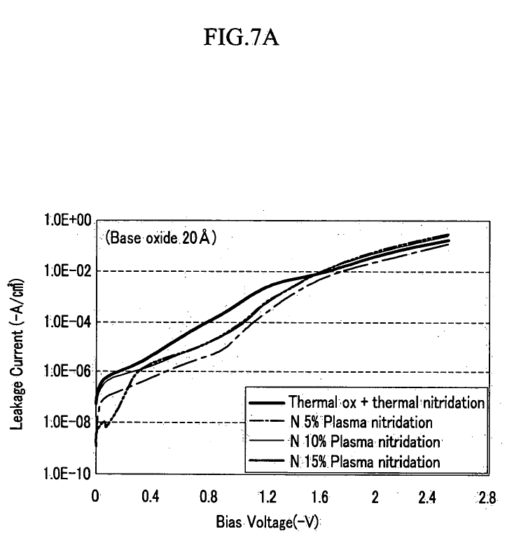

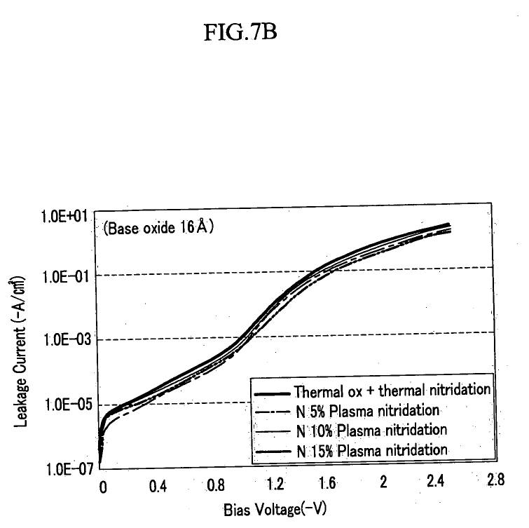

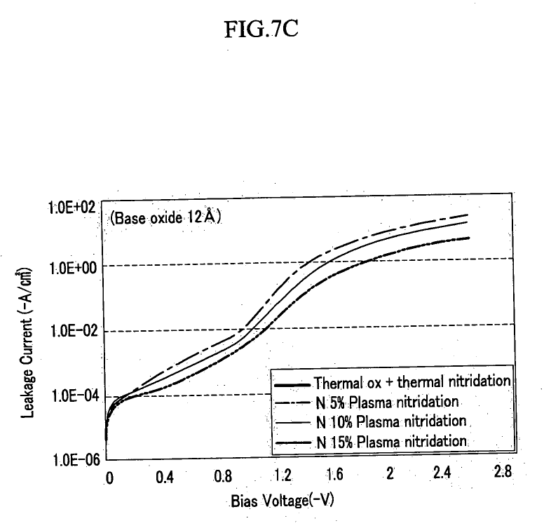

FIG. 7A to FIG. 7C are graphs of leakage currents in an NMOS transistor with respect to base oxide layers.

The leakage current is more sensitive to changes in bulk dielectric than to changes at the interface with a silicon substrate, since the pattern size (e.g., active area) may be large. However, leakage current may be compared indirectly for various concentrations of nitrogen.

When the base oxide layer has a thickness of 20 Å or 16 Å, the thermal nitride layer generally has a larger leakage current than the plasma nitride layer. In addition, regarding the leakage current as a function of the thickness of the base oxide layer, the leakage current tends to be smaller for lower nitrogen concentrations when the thickness of the base oxide layer is about 20 Å (or more), but the leakage current is generally independent of the nitrogen concentration when the thickness of the base oxide layer is around 16 Å, and the leakage current tends to be larger for lower nitrogen concentrations when the thickness of the base oxide layer is about 12 Å (or less).

From the above result, it may be understood that the leakage current model varies according to the thickness of the base oxide layer. That is, the leakage current tends to be more sensitive to the interface state when the thickness of the base oxide layer is greater than or equal to 20 Å, and when the thickness is 16 Å, the leakage current may become independent of the nitrogen concentration due to a compensating reaction between degradation at the interface and any variance in the thickness. However, when the thickness of the base oxide layer is 12 Å, the leakage current tends to be more sensitive to the bulk leakage current, and therefore it is reduced as the nitrogen concentration is increased.

That is, it may be understood that a gate oxide thickness of around 16 Å is a turning point at which an important factor affecting the leakage current may change from interface characteristics to bulk thickness (e.g., in relation to direct tunneling).

In addition, considering FIG. 7A and FIG. 7B along with FIG. 6A and FIG. 6B, it may be understood that, in thermal nitridation, a smaller amount of charge trap sites may form at the interface, and the leakage current may be larger because the nitrogen concentration at or near the interface may cause damage to the interface. That is, although the nitrogen at or near the interface may be combined with other elements, the interface may become unstable such that leakage current is generated.

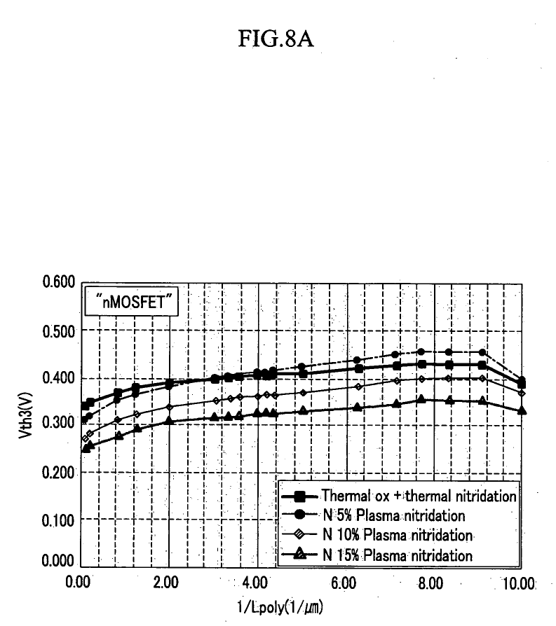

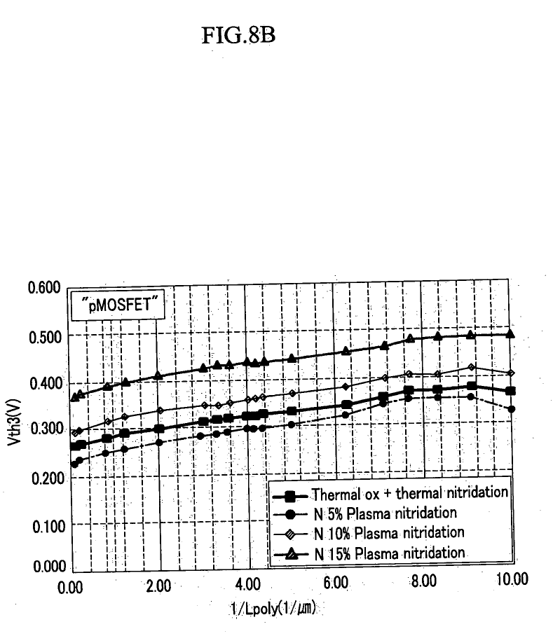

FIG. 8A and FIG. 8B are graphs of threshold voltages (Vth) with respect to lengths when a base oxide layer has a thickness of 20 Å.

As shown in FIG. 8A, a threshold voltage (Vth) of an NMOS FET tends to decrease as the nitrogen concentration of the gate insulator increases. In addition, the short channel effect (SCE) is almost identical for both the thermal nitride layer and the plasma nitride layer.

As shown in FIG. 8B, the threshold voltage (Vth) of a PMOS FET increases as the nitrogen concentration of the gate insulator increases, which is contrary to the case of the NMOS FET. From such data, it is generally understood that the nitrogen in the gate insulator prevents the boron penetration in the PMOS FET and reduces charge mobility in the NMOS FET. In addition, a reverse short channel effect (RSCE), rather than an SCE, occurs in the PMOS FET, from which it may be understood that the nitrogen effectively prevents boron penetration into the substrate.

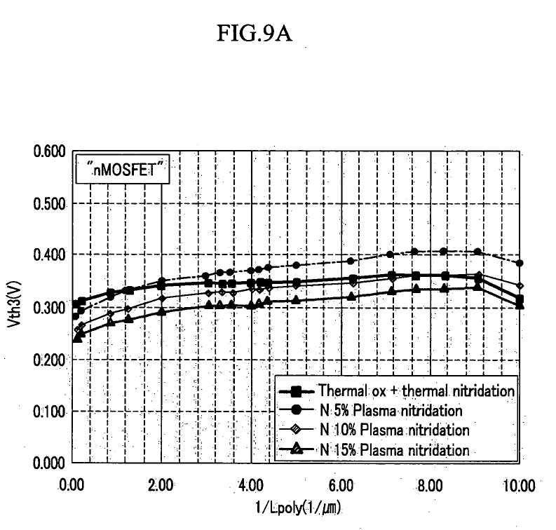

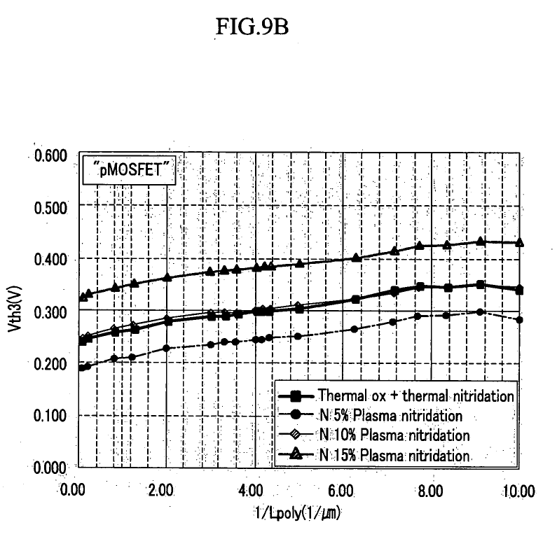

FIG. 9A and FIG. 9B are graphs of threshold voltages (Vth) with respect to lengths when a base oxide layer has a thickness of 16 Å.

According to the thermal nitridation method, the short channel effect (SCE) of the NMOS FET generally occurs more severely when the base oxide layer has a thickness of 16 Å than when the base oxide layer has a thickness of 20 Å. This may be caused by a concentration in the nitrogen profile at or near the interface between the gate oxide layer and the silicon substrate, so that a more severe SCE may occur for relatively shorter gate lengths.

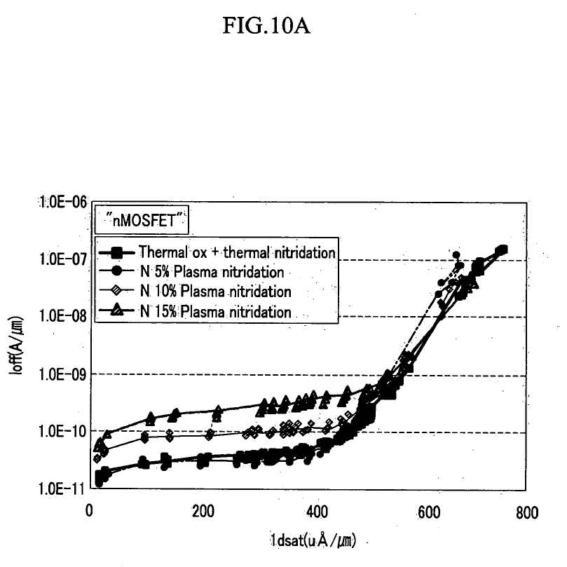

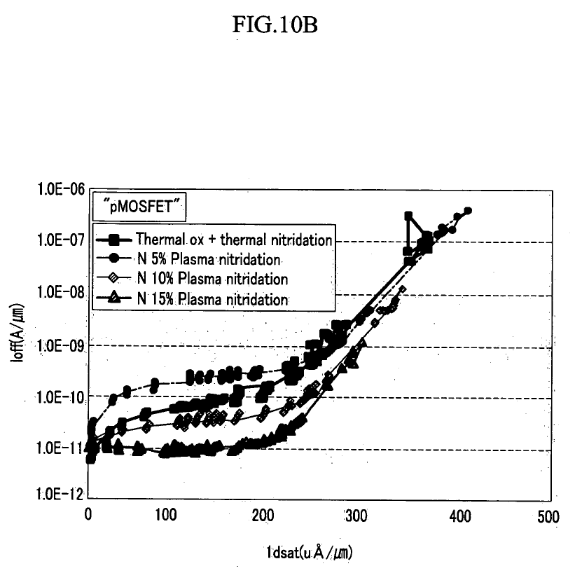

FIG. 10A and FIG. 10B are graphs of the on-current (Ion) and off-current (Ioff) characteristics of an NMOS FET and a PMOS FET when a base oxide layer has a thickness of 20 Å. The on-current (Ion) and off-current (Ioff) characteristics generally have the same tendencies as the threshold voltage (Vth) for the NMOS FET and PMOS FET. That is, when the nitrogen concentration increases in the NMOS FET, the off-current (Ioff) also tends to increase, and the on-current (that is, a saturation current) (Idsat) is generally preserved at about a predetermined level.

However, regarding the PMOS FET, the off-current Ioff tends to decrease as the nitrogen concentration increases. In addition, the on-current Idsat for a nitrogen concentration of 5% may be smaller than that for nitrogen concentrations of 10% and 15% over a range of applied currents. From this, it may be understood that plasma nitride layers formed at a nitrogen concentration of about 5% may not prevent boron penetration.

On estimating the plasma nitride layer based on the inverse of the oxide layer thickness (1/Tox) obtained from FIG. 5, the plasma nitride layer has a 3 Å thinner inverse oxide layer than the thermal nitride layer, when formed at a nitrogen concentration of about 10%. That is, the plasma nitride layer may have a smaller off-current than the thermal nitride layer for the same inverse oxide layer thickness.

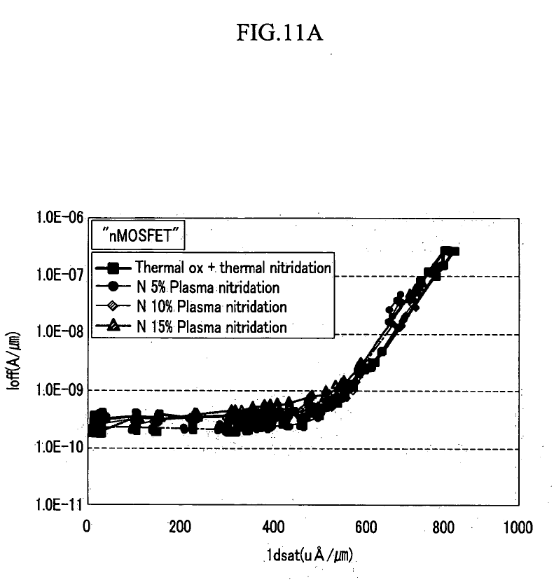

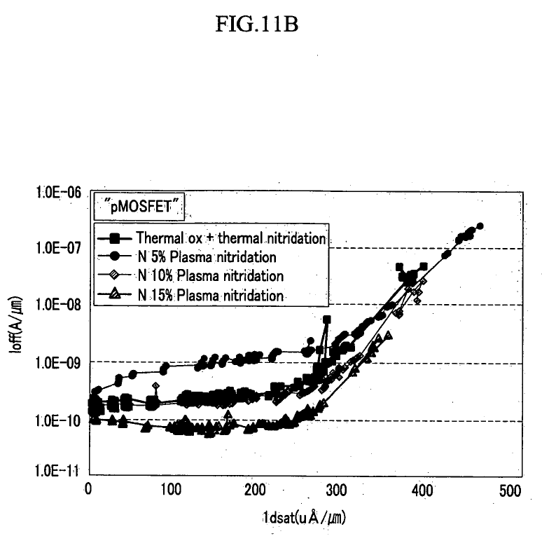

FIG. 11A and FIG. 11B are graphs of the on-current (Ion) and off-current (Ioff) characteristics of an NMOS FET and a PMOS FET when a base oxide layer has a thickness of 16 Å.

The NMOS FET and PMOS FET have almost the same on-current (Ion) and off-current (Ioff) characteristics for the 16 Å base oxide layer as for the 20 Å base oxide layer. When fabricated by plasma nitridation at a nitrogen concentration of about 10%, the PMOS FET has a more enhanced performance than when fabricated by thermal nitridation.

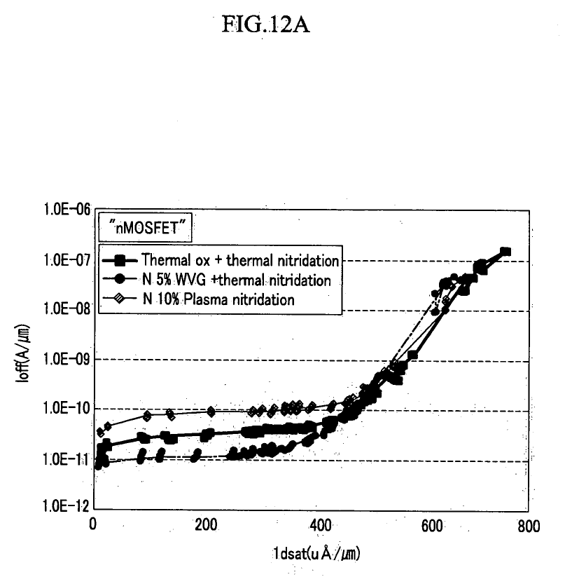

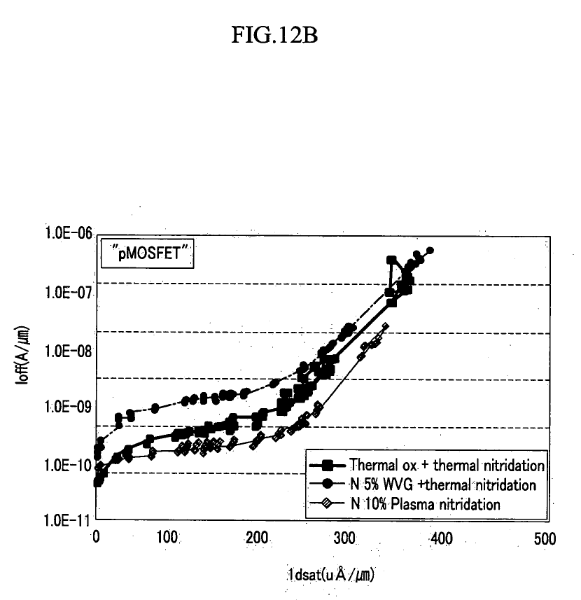

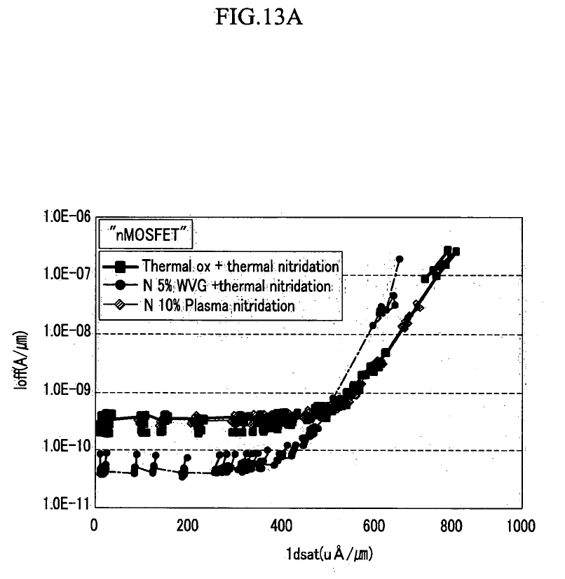

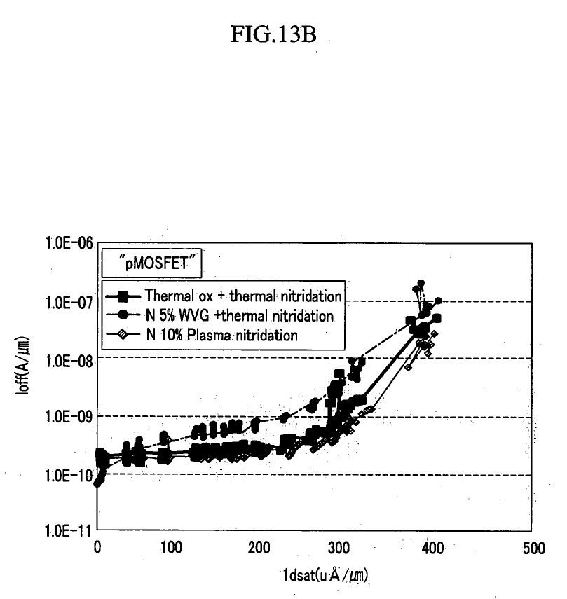

FIG. 12a to FIG. 13B are graphs of on-current (Ion) and off-current (Ioff) characteristics according to the oxidation and nitridation methods. Plasma nitridation results in an enhanced performance (in many cases by about 20%) over a thermal nitridation method, regardless of how the gate oxide layer is formed (e.g., torch thermal oxidation vs. WVG).

As described above, the performance of the thin film transistor may be dependent on the nitrogen depth profile in the gate oxide layer, and the nitride depth profile is generally dependent on the nitridation method. For example, thermal nitride layers generally have a nitrogen concentration maximum at or near the interface between the silicon substrate and the oxide layer, while plasma nitride layers generally have a nitrogen concentration maximum at or near the upper surface of the oxide layer.

In addition, a thickness of around 16 Å for the gate oxide layer (prior to nitridation) may be a turning point at which an important factor affecting the leakage current changes from interface characteristics to bulk thickness (e.g., in relation to direct tunneling).

In addition, when the same base oxide layer is used, the optical thickness can be sensitive to the nitrogen concentration.

When plasma nitridation is performed on a 16 Å base oxide layer using a plasma gas having less than a 10% N₂ concentration, the Idsat and Ioff characteristics can be appropriate for the 90 nm or less design rule.

According to an exemplary embodiment of the present invention, plasma nitridation is used so that charge mobility can be preserved for the NMOS transistor, and the boron penetration can be prevented for the PMOS transistor, in semiconductor devices having 100 nm or less gate length.

While this invention has been described in connection with what is presently considered to be the practical exemplary embodiment, it is to be understood that the invention is not limited to the disclosed embodiments, but, on the contrary, is intended to cover various modifications and equivalent arrangements included within the spirit and scope of the appended claims.

What is claimed is:

1. A method of manufacturing a semiconductor device, comprising:
forming a gate oxide layer on a substrate; and
forming a nitride layer on the surface of the oxide layer using a plasma gas comprising nitrogen.

2. The method of claim 1, wherein in forming the nitride layer, the nitrogen has a concentration of 10%.

3. The method of claim 1, wherein in forming the nitride layer, a processing chamber containing the plasma has a pressure of from 6 to 8 Pa.

4. The method of claim 3, wherein the pressure is about 7 Pa.

5. The method of claim 1, wherein forming the gate oxide layer comprises wet oxidation.

6. The method of claim 1, wherein forming the gate oxide layer comprises a WVG (water vapor generator) method.

7. The method of claim 1, wherein the gate oxide layer has a thickness of from 10 to about 20 Å.

8. The method of claim 6, wherein the gate oxide layer has a thickness of about 16 Å.

9. A semiconductor device comprising:
a silicon substrate;
a gate oxide layer on the silicon substrate; and
a nitride layer concentrated on a surface of the gate oxide layer using a plasma gas comprising nitrogen in a predetermined concentration.
